(19) United States
(12) Patent Application Publication
(10) Pub. No.: US 2014/0016996 A1
(43) Pub. Date: Jan. 16, 2014

(54) LATCHING STRUCTURE FOR PORTABLE ELECTRONIC DEVICE AND DETACHING METHOD

(71) Applicants: FIH (Hong Kong) Limited, Kowloon (HK); SHENZHEN FUTAIHONG PRECISION INDUSTRY CO., LTD., Shenzhen (CN)

(72) Inventors: HUAN-CHANG CHUNG, Shindian (TW); GANG YANG, Shenzhen (CN); ZHONG-SHU QIN, Shenzhen (CN)

(21) Appl. No.: 13/911,026

(22) Filed: Jun. 5, 2013

(30) Foreign Application Priority Data
Jul. 16, 2012 (CN) 2012102449590

(51) Int. Cl. H05K 5/02; H05K 13/00

(52) U.S. Cl. CPC H05K 5/0221; H05K 13/00
USPC 403/321; 29/426.1

(57) ABSTRACT

A latching structure is configured for a portable electronic device including a first housing and a second housing. The latching structure includes a latching groove and a hook. The latching groove is defined the first housing, and a removable portion is formed in the latching groove. The hook is formed on a second housing. The hook latches in the latching groove. The removable portion is separated from the first housing to expose the latching groove for pushing the hook out of the latching groove.

### BACKGROUND

1. Technical Field

The present disclosure relates to a latching structure for portable electric device with two housings and a method for detaching the latching structure.

2. Description of Related Art

Portable electronic devices such as mobile phones, laptops and personal digital assistants (PDAs) use incorporate at least two housings.

Typical housings of a portable electronic device include an upper housing and a lower housing. The upper housing may be latched to the lower housing. However, engagement between the two housings can be too firm to be easily undone.

Therefore, there is room for improvement within the art.

### BRIEF DESCRIPTION OF THE DRAWINGS

Many aspects of the latching structure and detaching method can be better understood with reference to the following drawings. The components in the drawings are not necessarily drawn to scale, the emphasis instead being placed upon clearly illustrating the principles of the latching structure and detaching method. Moreover, in the drawings like reference numerals designate corresponding parts throughout the several views.

FIG. 1 shows an exploded, schematic view of an exemplary embodiment of an electronic device with a latching structure.

FIG. 2 is similar to FIG. 1, but shown from a different aspect.

FIG. 3 is an assembled view of the portable electronic device.

FIG. 4 is a cross sectional view of the latching structure taken along line IV-IV in FIG. 3.

FIG. 5 is a schematic view of a tool for detaching the portable electronic device.

FIG. 6 is a cross sectional view of one part of the portable electronic device received in the tool for detaching.

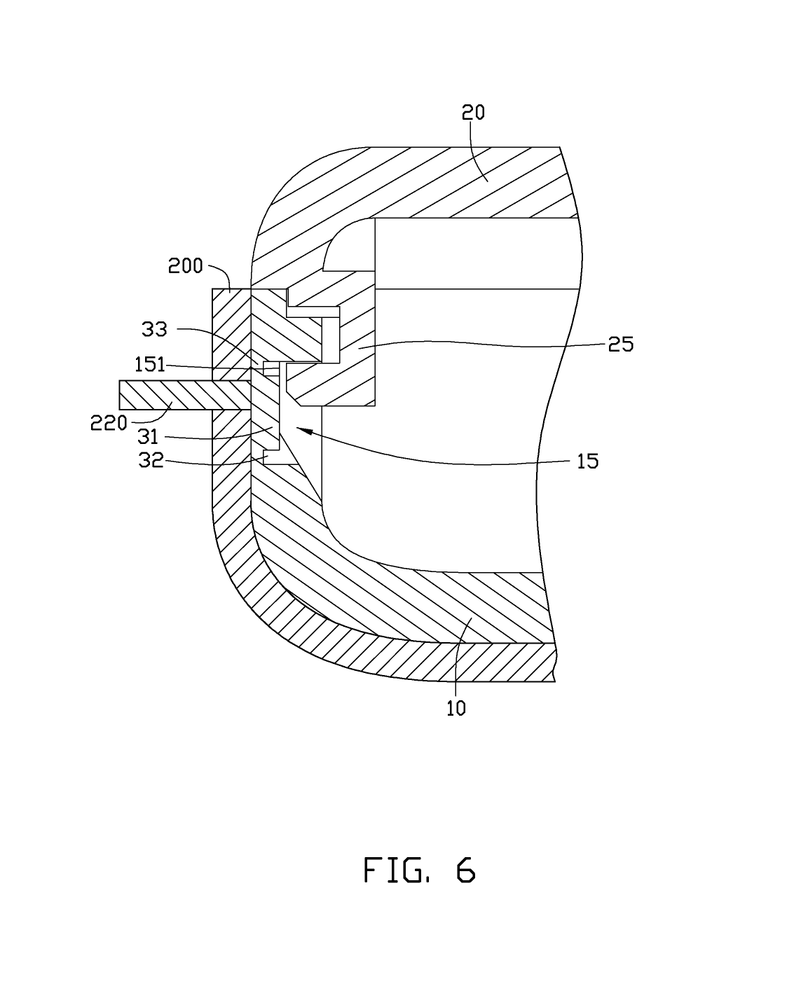

FIG. 7 is similar to FIG. 4, but showing the removable portion to be removed.

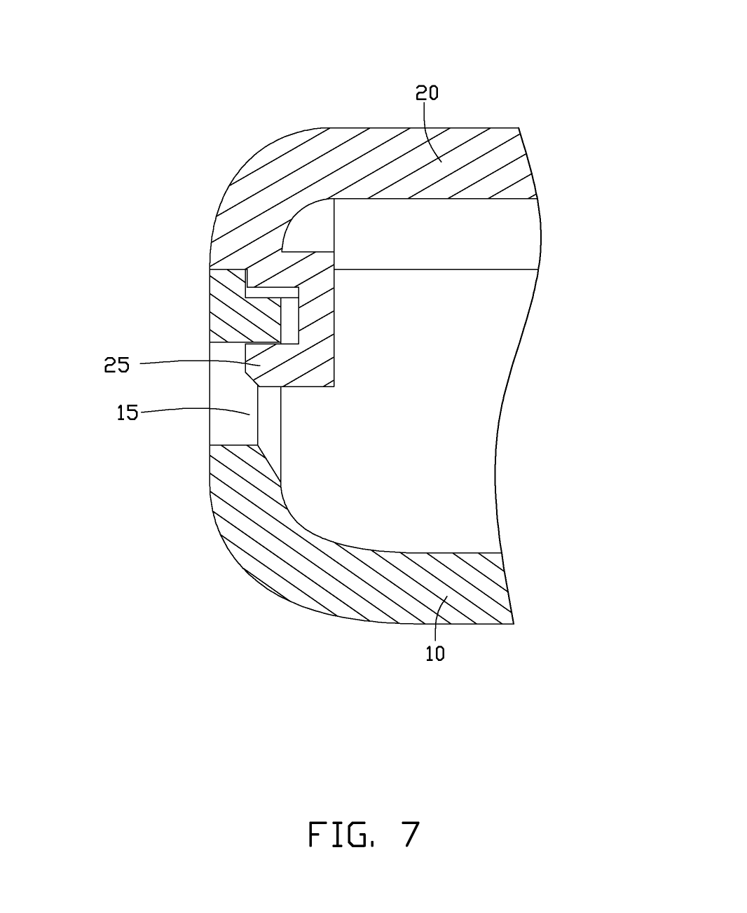

### DETAILED DESCRIPTION

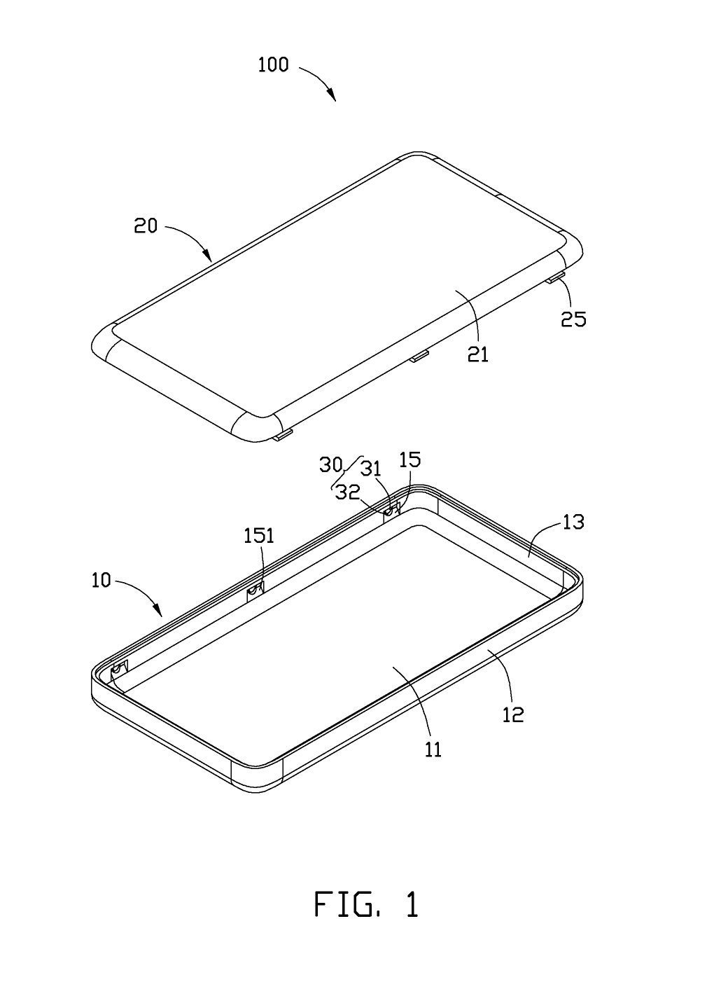

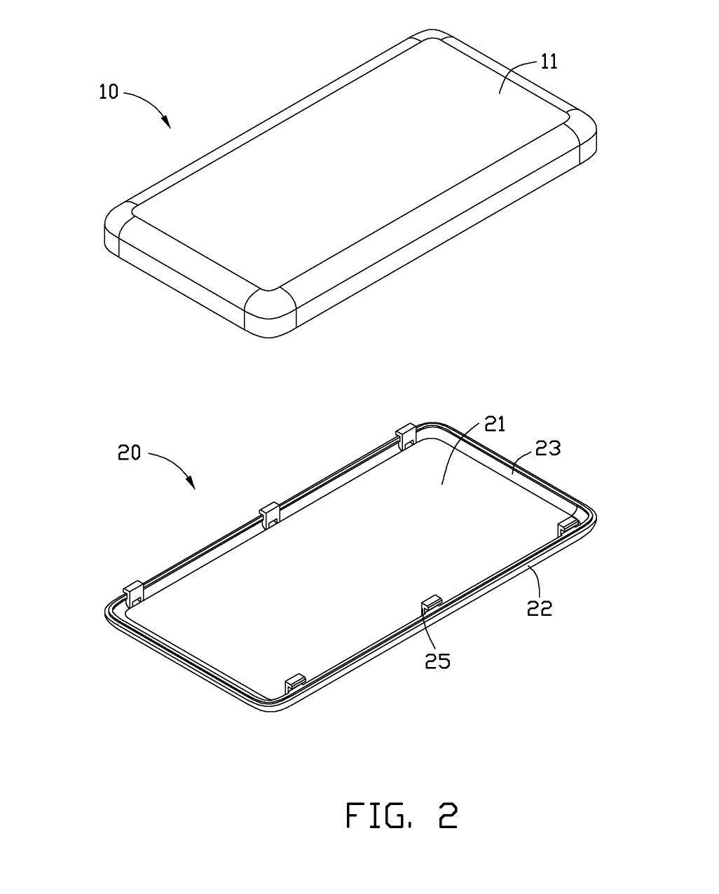

FIGS. 1 and 2 illustrate an exemplary embodiment of a portable electronic device 100. The portable electronic device 100 comprises a first housing 10 and a second housing 20 releasably latched on the first housing 10.

The first housing 10 can be formed by injection molding a moldable material. The moldable material can be made of a resin material (e.g. polycarbonate). In one exemplary embodiment, the first housing 10 has a base plate 11, two opposite side edges 12, and two opposite end edges 13. The two opposite side edges 12 and the two opposite end edges 13 are connected to a peripheral edge of the base plate 11. An inner surface of each side edge 12 defines at least one latching groove 15 and a removable portion 30 in the latching groove 15. The latching groove 15 has a bottom wall 151. The removable portion 30 has a projection 31 formed on the bottom wall 151. A ring recess 32 is around the projection 31 and thus forms a ring neck 33. The ring neck 33 is less thick than the projection 31. When an outer force is applied on the removable portion 30, the removable portion 30 can be broken along the ring neck 33. In this exemplary embodiment, there are six latching grooves 15 respectively and symmetrically defined in the two opposite side edges 12.

The size and shape of the second housing 20 corresponds to the size and shape of the first housing 10. The second housing 20 can be formed by injection molding a resin material (e.g. polycarbonate). The second housing 20 has a main body 21, two sidewalls 22, and two end walls 23 connected to a peripheral edge of the main body 21. The sidewalls 22 has at least one hook 25 corresponding to the latching groove 15 of the first housing 10. In this exemplary embodiment, there are six hooks 25 formed on the two opposite sidewalls 22 corresponding to the latching grooves 15.

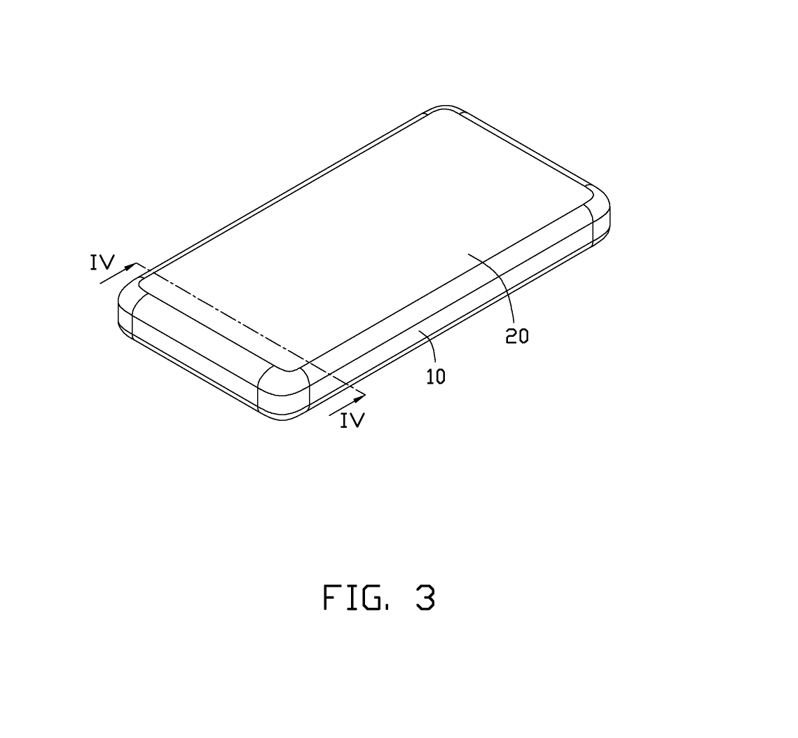

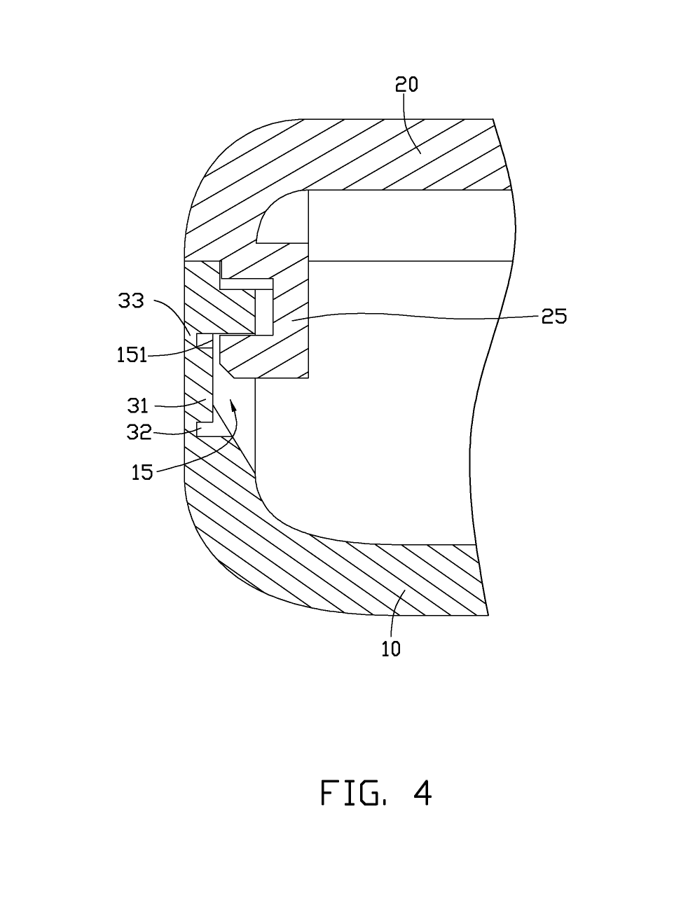

Referring to FIGS. 3 and 4, the second housing 20 is positioned on the first housing 10, and the hooks 25 are aligned with the latching grooves 15. Then, the second housing 20 is pressed against the first housing 10 to allow the hooks 25 to latch in the latching grooves 15.

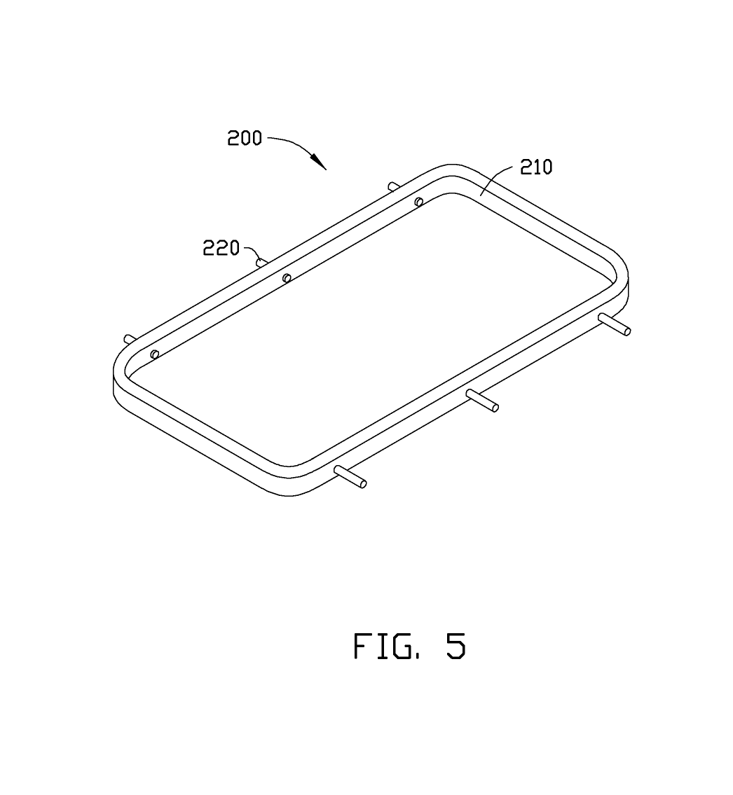

FIG. 5 shows that a removing tool 200 is provided for detaching the second housing 20 from the first housing 10. The removing tool 200 has a receiving cavity 210. An inner wall of the receiving cavity 210 has a plurality of ejecting pins 220. The ejecting pins 220 can be slid toward the inside of the receiving cavity 210. The arrangement of the ejecting pins 220 correspond to the position of the removable portions 30. To detach the second housing 20 from the first housing 10, the assembled portable electronic device 100 is received in the receiving cavity 210. The ejecting pins 220 faces with an outer surface of the side edge 12 of the first housing 10 and are aligned with the removable portions 30 of the side edges 12. The ejecting pins 220 are driven to press against the removable portions 30. The removable portions 30 are forced to be broken along the ring necks 33 from the side edges 12. Each removable portion 30 falls inside of the first housing 10 and the corresponding latching groove 15 is exposed from the first housing 10. Simultaneously, the ejecting pins 220 are further driven to push the hooks 25 from the latching grooves 15.

It should be also understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A latching structure configured for a portable electronic device with a first housing and a second housing, comprising:
a latching groove defined the first housing, a removable portion formed in the latching groove;
a hook located on the second housing, the hook latching with the latching groove;
wherein the removable portion is separated from the first housing to expose the latching groove for pushing the hook out of the latching groove.

2. The latching structure as claimed in claim 1, wherein the removable portion comprises a projection formed on a bottom wall of the latching groove, a ring recess is around the projection, and a ring neck is formed on the bottom wall; and the ring neck allows the removable portion is broken along the ring neck.

3. The latching structure as claimed in claim 1, wherein the first housing comprises a base plate, two opposite side edges, and two opposite end edges; the two opposite side edges and the two opposite end edges are connected to a peripheral edge of the base plate; and an inner surface of each side edge defines the latching groove.

4. The latching structure as claimed in claim 3, wherein the second housing comprises a main body, two sidewalls, and two end walls connected to a peripheral edge of the main body; and the sidewalls have the hook corresponding to the latching groove.

5. A method for detaching a portable electronic device, comprising the step of:
providing a removing tool comprising a plurality of ejecting pins;
positioning the portable electronic device in the removing tool, the portable electronic device comprising a first housing and a second housing; a plurality of latching grooves defined in the first housing, a removable portion formed in each latching groove, a plurality of hooks formed on a second housing, the hooks latching in the latching grooves;
aligning the ejecting pins with the removable portions;
pressing the ejecting pins against the removable portions to separate the removable portions from the first housing to expose the latching grooves for pushing the hooks out of the latching grooves.
